(19) United States
(12) Patent Application Publication
(10) Pub. No.: US 2009/0102415 A1
(43) Pub. Date: Apr. 23, 2009

(54) Suitcase power system

(76) Inventors: David J. Muchow, Arlington, VA (US); Sara V. Zulkosky, Arlington, VA (US); Hugh Jones, Canastota, NY (US)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/213,876

(22) Filed: Jun. 25, 2008

Related U.S. Application Data
(60) Provisional application No. 60/929,370, filed on Jun. 25, 2007.

(51) Int. Cl. H02J 7/00; F24J 2/46; B64C 11/28; H01L 21/00; B65D 85/68; B65D 77/00

(52) U.S. Cl. 320/101; 126/627; 416/142; 206/319; 126/624; 206/216; 320/137; 414/800

(57) ABSTRACT

A closeable case includes a power system stored in an interior of the closeable case. The closeable case includes a power system, and at least a portion of the power system is integral to the closeable case. The closeable case also includes at least one power generating device stored in the closeable case and at least partially removable from the closeable case.

### PRIORITY

This application claims the benefit of priority from U.S. Provisional Application No. 60/929,370, filed Jun. 25, 2007, which is herein incorporated by reference in its entirety.

### TECHNICAL FIELD

The present disclosure relates generally to a portable power system, and more particularly, to a suitcase or smaller sized container or housing having a power system.

### BACKGROUND

While electric power from traditional electrical grids is readily available in many locations throughout the world, there remain vast regions where no electric power is available. Even in locations where electric power is available, there are a variety of situations where a supplemental or substitute power source would be desirable.

Solar, wind, and other power generating devices are known and may be applied in many different applications. Traditional solar and wind power generating devices, however, have several shortcomings. For example, these devices have not been rapidly deployable and small enough to be easily transported by one person, in a form such as airline-checkable luggage. In addition, the components are not generally standardized. As a result, they must be custom built for each particular application, which makes these devices expensive. Custom built solar or wind power generating devices with or without batteries and control systems, typically require days to assemble or to disassemble. Further, these traditional power generating devices are not modular for easy expansion or replacement of parts. Specifically, once a particular solar or wind power generating device has been designed and manufactured to include a certain number of photovoltaic or wind power generating devices, additional devices may not be added to the system without significant difficulty including, for example, redesign and modification of the generator.

There currently exists a need for a standardized, modular, capable of being rapidly assembled, airline checkable (or smaller or larger), hybrid power generator that can operate either on the power grid or in remote places and that is easily transportable by one person to address these issues.

### SUMMARY

A closeable case includes a power system stored in an interior of the closeable case. The closeable case includes a power system, and at least a portion of the power system is integral to the closeable case. The closeable case also includes at least one power generating device stored in the closeable case and at least partially removable from the closeable case.

A transportable power system includes a first closeable case for storing at least one power generating device and at least one first battery. The at least one power generating device is removable from the first closeable case. The transportable power system also includes a second closeable case for storing at least one second battery. The first and second batteries are capable of receiving power from the at least one power generating device.

A method of transporting a closeable case includes storing a power generating device within the closeable case, carrying the closeable case to a desired location, and removing at least a portion of the power generating device from within the closeable case. The method also includes receiving power from the power generating device and providing access to the received power.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1 is a schematic view of a first layer of an interior of an exemplary disclosed suitcase having a smaller or larger housing with a hybrid power system provided therein;

FIG. 2 is a schematic view of a second layer of the interior of the suitcase of FIG. 1;

FIG. 3 is a plan view of an exemplary disclosed solar array of the power system of FIGS. 1 and 2;

FIG. 4 is a plan view of an exemplary disclosed solar panel of the solar array of FIG. 3;

FIG. 5 is a side view of an exemplary disclosed sub-array of the solar array of FIG. 3 in a partially folded configuration;

FIG. 6 is a plan view of the sub-array of FIG. 5 in a folded configuration;

FIG. 7A is a schematic view of an exemplary disclosed solar blanket prior to insertion of the solar panel;

FIG. 7B is a schematic view of an exemplary disclosed solar blanket with the solar panel inserted in the solar blanket;

FIG. 7C is a schematic view of an exemplary disclosed solar blanket with the solar panel fastened inside the solar blanket;

FIG. 8 is a schematic view of an exterior of an exemplary disclosed suitcase with a removably attachable battery system;

FIG. 9 is a schematic view of a first layer of an interior of another exemplary disclosed suitcase having a smaller or larger housing with a hybrid power system provided therein; and

FIG. 10 is a schematic view of a second layer of the interior of the suitcase of FIG. 9.

### DESCRIPTION OF THE EMBODIMENTS

Reference will now be made in detail to exemplary embodiments of the invention, examples of which are illustrated in the accompanying drawings. Wherever possible, the same reference numbers will be used throughout the drawings to refer to the same or like parts.

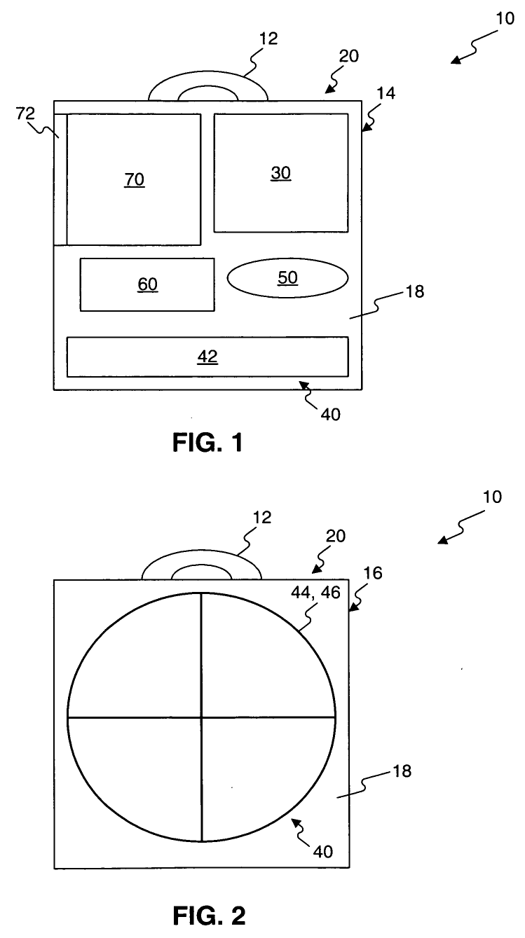

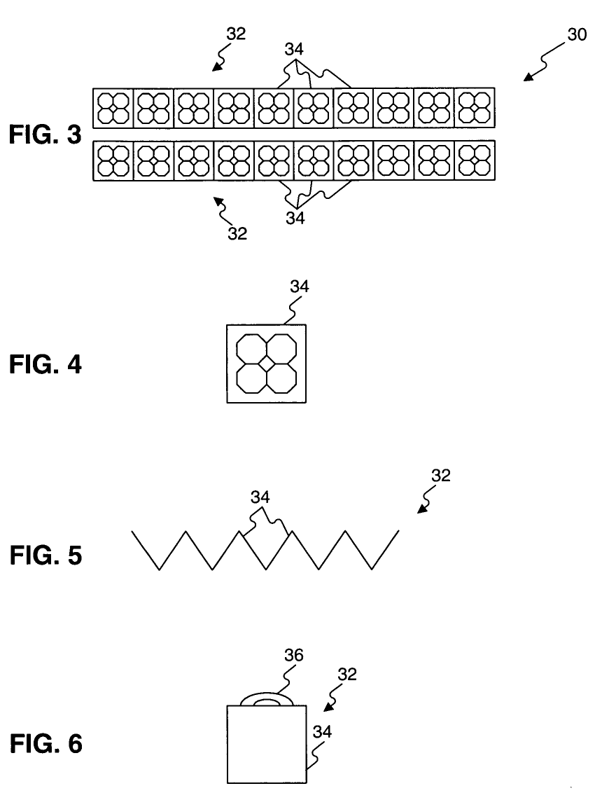

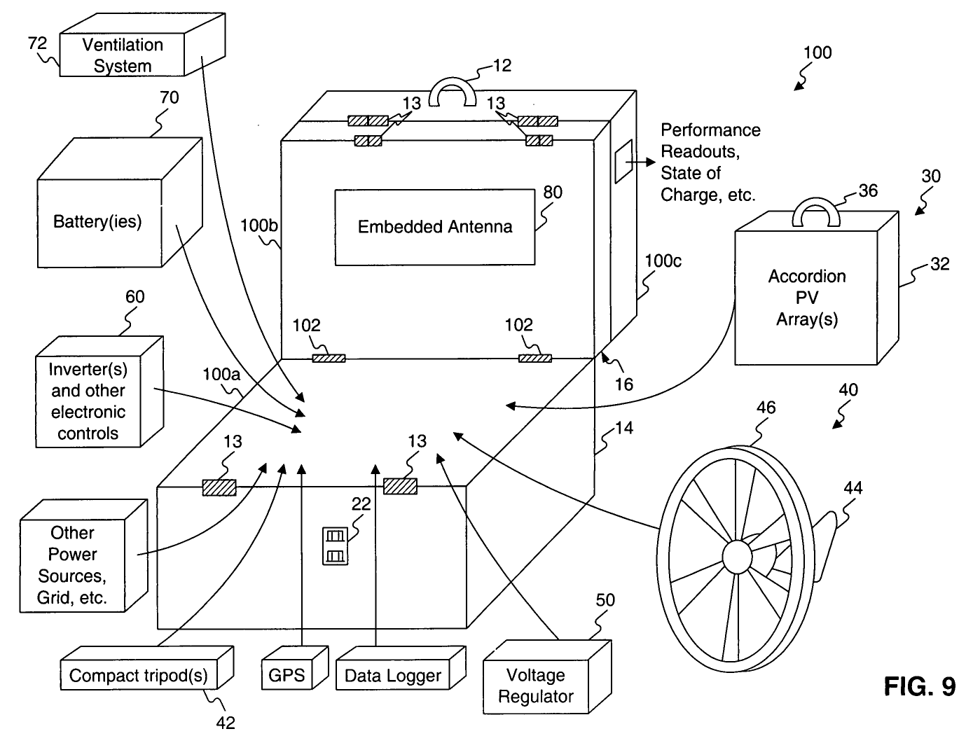

FIGS. 1 and 2 show an interior of a portable container or housing, such as a suitcase 10, a backpack, a crate, a trunk, or other type of carrying case. As described herein, it is to be understood that another type of container, such as a housing, may be used instead of a case. The suitcase 10 contains a power system 20 that resides in and is integrated with the suitcase 10. The suitcase 10 may include a handle 12 to allow a user to carry the suitcase 10 and a closing or locking mechanism 13 (FIG. 9). The locking mechanism 13 may include requiring operational codes to be entered, twist locks, and/or retina or fingerprint systems to electronically or mechanically activate or deactivate the devices and accessories of the suitcase 10 and power system 20. The suitcase 10 may also be configured with other safety/security components, such as, a self-destruct mechanism. During transport, the power system 20 may be inaccessible from the outside of the suitcase 10. Alternatively, the power system 20 may include solar panels 34 (FIGS. 3-6) that may be attached to the exterior of the suitcase 10 to provide power when the suitcase 10 is closed, in transit, or in other situations. The suitcase 10 and some of its components may be made of edible components to provide food in extreme situations. The power system 20 may be protected by the suitcase 10 from outside elements, such as dust, debris, liquids, etc. After the suitcase 10 is delivered to a desired operating location, the suitcase 10 may be opened so that the power system 20 may transmit power to one or more pieces of equipment, such as communications equipment, laptops, cell phones, etc., or the power grid.

The power system 20 includes at least one power generating device, such as a solar array, a wind turbine, a fuel cell, a microturbine, and/or other power generating device, which may be deployed to generate power. In addition, the power system 20 may include one or more other power sources, grids, etc. In the embodiment shown in FIG. 1, the power system 20 includes both a solar array and a wind turbine power generating device. The power system 20 may be operated continuously to satisfy a steady-state 24-hour continuous power requirement. For example, the power system 20 may provide a continuous power output of, e.g., 200 watts with intermittent 400 watts spikes as required to serve fluctuating loads. Actual output of the power system 20 may vary depending on solar irradiation on site, wind, water flow, weather, etc.

The suitcase 10 may be including a smaller or larger housing and may be airline-checkable, waterproof, crushproof, dustproof, chemical-resistant, e.g., a Pelican™ case. The suitcase 10 may be constructed to meet domestic airline regulations for weight and size. For example, the suitcase 10 may weigh less than 70 pounds, and the total sum of the dimensions of the suitcase 10 may be less than 62 inches. The suitcase 10 may be weather-tight, strong, and with foam-like materials inside, and durable to protect all of the components in the suitcase 10. The suitcase 10 may be easy to transport and may allow for rapid deployment of the power generating devices provided inside the suitcase 10. Furthermore, the suitcase 10 may provide a sturdy, protective housing for the power system 20. The power system 20 (or some of its components) may be separately encased and accessible only for servicing. The suitcase 10 and the components of the power system 20 included inside the suitcase 10 may be rugged such that the suitcase 10 and power system 20 may withstand harsh environments. For example, the suitcase 10 may be made with bulletproof or bullet resistant material. Even further, the suitcase 10 may include photovoltaic material on all or part of the outer surface of the suitcase 10. Further, in certain embodiments, the suitcase 10 may be controllable to allow the system to float and/or be submerged.

The exterior dimensions of the suitcase 10 may be approximately 24 inches (length)×24 inches (width)×14 inches (depth). The interior dimensions of the suitcase 10 may be approximately 23 inches (length)×23 inches (width)×10 inches (depth). The suitcase 10 may be capable of housing all of the components of the power system 20. In yet other embodiments, the suitcase may be formed of a non-conventional shape to resemble an inanimate object, such as a rock, or may be otherwise shaped or colored to provide camouflage.

The suitcase 10 may include a fold-down or other collapsible handle 12 and wheels (not shown) for transport. The wheels may be designed to be powered by the power system 20 so that the suitcase 10 may be moved autonomously. A deployable parachute may be attached to the suitcase 10, or formed integral therewith, to allow for delivery of the suitcase from the air. In certain embodiments, the suitcase 10 may be controllable under water using one or more microturbines or other propulsion for use to transport persons and/or equipment. Alternatively or in addition, the microturbines may be used to generate power when the suitcase 10 is floating or submerged in moving liquid. This may be accomplished by anchoring or otherwise fixing the suitcase 10 in position.

FIGS. 1 and 2 show two layers of components stored within the suitcase 10. FIG. 1 shows a first or bottom layer 14 of components, and FIG. 2 shows a second, or top layer 16 of components. As shown in FIG. 1, the first layer 14 may include space for storing components of the power system 20 such as an accordion fold-out solar (or photovoltaic) array 30, a tripod 42 of a rapidly-deployable wind turbine system 40, a voltage regulator 50, an inverter 60 (e.g., an inverter rated at 700 watts) and/or other electronic controls, and a battery system 70 for back-up power.

As shown in FIG. 2, the second layer 16 may include space for storing components of the power system 20 such as removable or fixed wind turbine blades 44 and a wind turbine body 46. For example, the body 46 of the wind turbine may be positioned under the blades 44 and may point down in the suitcase 10 toward the battery system 70 in the first half 14 of the suitcase, when the suitcase 10 is closed. Alternatively, instead of providing the wind turbine system 40 inside the suitcase 10, the wind turbine system 40 may be provided in one or more separate suitcases. As a result, the wind turbine system 40 may be stored in a separate suitcase during shipping, and then attached to the suitcase 10 (e.g., the power system 20 in the suitcase) after shipping and prior to use.

The components of the power system 20 may be separated and safeguarded from each other using flexible foam 18, straps/cables (not shown), etc., when stowed inside the suitcase 10. The voltage regulator 50, the inverter 60, and the battery system 70 may be permanently integrated into the suitcase 10. The solar array 30 and the wind turbine system 40 may be removable from the interior of the suitcase 10 and may be put back into the interior of the suitcase 10 so that the suitcase 10 and the power system 20 may be transported again to another location.

The power system 20 may also include receptacles (not shown) for storing power cords (not shown) that allow the power system 20 to plug and play with the equipment and other devices to be powered by the power system 20. The power system 20 may include multiple sockets 22 (FIG. 9) for connecting various input connectors (not shown) that connect to the power generating devices (e.g., the solar array 30 and the wind turbine system 40), the power grid, or other power sources, and various output connectors (not shown) for connecting to the equipment and devices to be powered. The input and output connectors may be configured for numerous different types of power connectors to provide increased versatility. The sockets 22 may be integrated inside the suitcase 10 or may be provided on an external surface of the suitcase 10. Optionally, one or more displays (not shown), power meters (not shown), indicator lights (not shown), and/or light-emitting diodes (LED) or other lights for operating with ease at night may also be provided in the power system 20. Such devices may be placed in and/or visible from the interior or exterior of the suitcase 10, and may be used to indicate one or more performance characteristics of the power system 20 (e.g., performance readouts, state of charge of the battery system 70, etc.). To comply with transportation safety regulations, electrical disconnects may be provided to separate the batteries from input/output circuits during transport.

The power system 20 may also include data logging equipment (not shown) including, e.g., a global positioning (GPS) antenna/satellite system (not shown), and a transmitting device, such as a transceiver or antenna 80 (FIG. 9), to allow the power system 20 to be remotely monitored and/or controlled. For example, the data logging equipment may communicate information to one or more remote facilities or other monitoring facilities and devices. The power system 20 may include CBW and other types of sensing systems, and/or antenna 80 and GPS antennas. The antenna(s) 80 may be deployable or embedded into the suitcase 10. Even further, the suitcase 10 may be configured to dispense marker dyes or other tracking mechanisms. These components of the power system 20 may be combined to create a highly reliable, hybrid power system for use outdoors in the field. Further, the antennas 80, transmitting devices, and/or other accessories may be disguised as a flora, fauna, etc., to avoid detection. The power system 20 may also automatically configure or allow the user to configure the input and/or output configuration of the power system 20 so that particular loads and/or internal needs (e.g., the battery system 70) are prioritized.

FIGS. 3-6 illustrate the solar array 30 including one or more sub-arrays 32. FIG. 3 shows a solar array 30 including two parallel sub-arrays 32. According to the embodiment shown in FIG. 3, each sub-array 32 may include a chain of linked solar panels 34, e.g., ten solar panels. In one embodiment, each sub-array 32 may be approximately 115 inches long, and the entire solar array 30 may provide a power output of approximately 276 watts. FIG. 4 shows a single solar panel 34. In one embodiment, each solar panel 34 may output approximately 13.8 watts. It is to be understood that each sub-array 32 may include multiple solar panels 34 in other types of configurations and is not limited to a chain-like configuration. The solar array 30 is also modular, allowing the user to customize the solar array 30 by mixing, matching, adding, and removing sub-arrays 32 and solar panels 34 to achieve a higher or lower power requirement.

Each sub-array 32 may be an accordion-type honeycomb photovoltaic (PV) array. Honeycomb sub-arrays are sturdy and durable since they include solar panels 34 that may be folded and that allow the sub-arrays to be modular. Alternatively, the sub-array 32 may be a thin-film sub-array. However, the honeycomb sub-array 32 may be more powerful, sturdier, and more durable than the thin-film sub-array. As a result, the rigid honeycomb photovoltaic sub-array 32, which may also have a higher output, may be configured to be more rapidly deployable and more portable. In addition, the honeycomb structure allows the solar panels 34 to float.

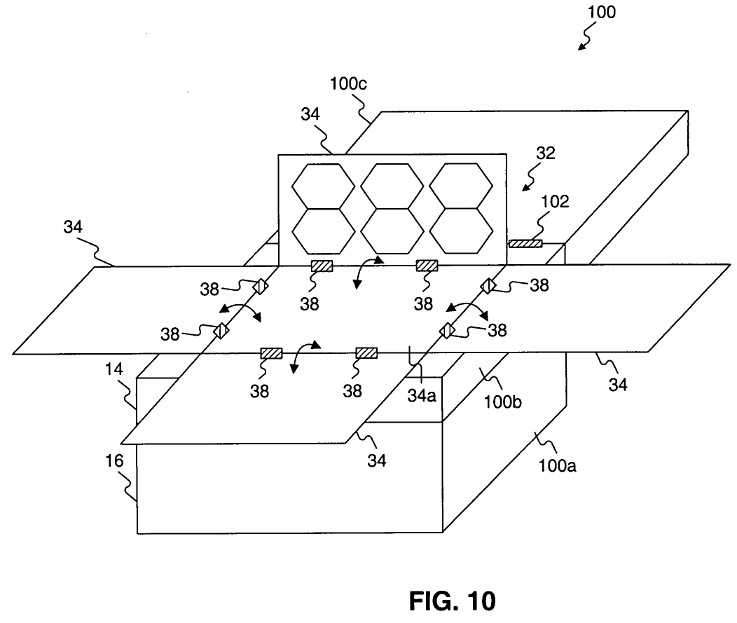

Each solar panel 34 may be connected to adjacent solar panels 34 via hinges 38 (FIG. 10). The accordion design of the sub-arrays 32, which is shown in FIG. 5, allows for stowage of each sub-array 32 inside the suitcase 10 by folding the sub-arrays 32 neatly and compactly so that the folded sub-arrays 32 may be stored in the suitcase 10. The accordion design also allows the sub-array 32 to be rapidly deployable. When deployed to generate solar power, the sub-arrays 32 may lie flat or in a partially-folded configuration as shown in FIG. 5. FIG. 6 shows the sub-array 32 in a completely folded configuration. A handle 36 may be provided to serve as a closing device that secures the sub-array 32 in the folded configuration for stowage and that allows the user to transport the sub-array 32 by hand.

In an alternative embodiment, the suitcase 10 may be configured to include a built-in base solar array in the form of a pancake-type stack of solar panels 34 to provide maximum power in a limited space. In such an arrangement, for example, square solar cells may unfold in a plurality of directions from a central base solar cell. The integral solar cells unfolded from the suitcase 10 may be used alone to provide power to power system 20, or sub-arrays 32 may be coupled to one or more of the unfolded solar cells to provide greater power generation.

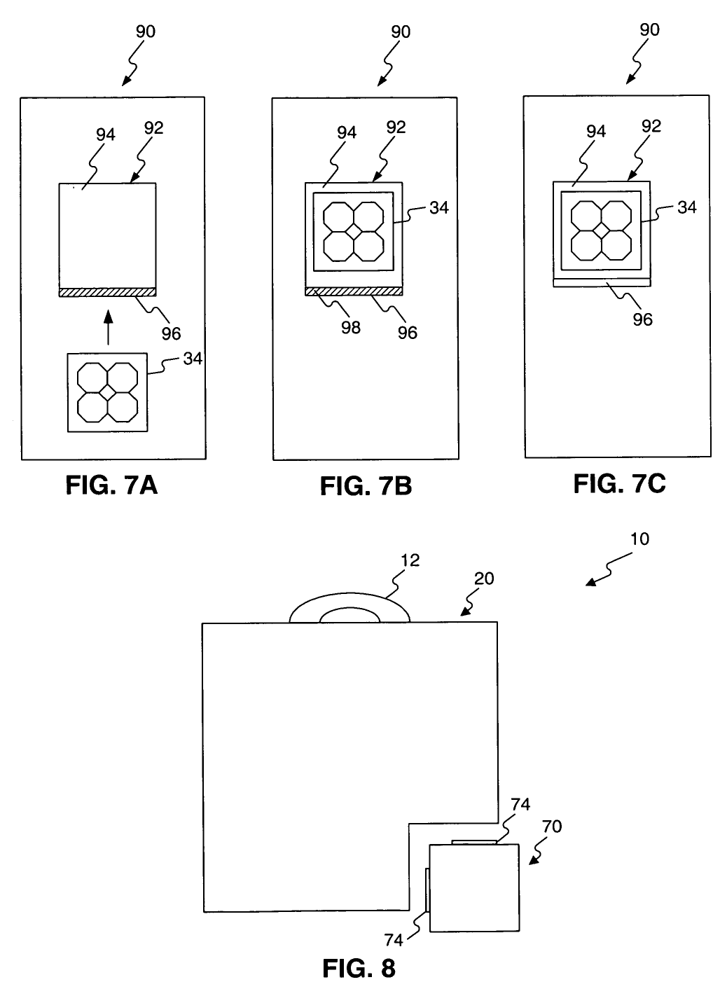

As another alternative, higher power crystalline solar panels 34 could be attached to a honeycomb or other substrate. As shown in FIGS. 7A-7C, the honeycomb may in turn be attached to a flexible plastic or canvas-type material to form a solar blanket 90 which could plug into the suitcase 10. This provides substantially more power than the traditional flexible solar material used in flexible solar applications. In addition, when honeycomb material is used in the substrate, the blanket 90 may float or operate under water. The blanket 90 may be easily folded and stowed in the suitcase 10. The blanket 90 may be held in the folded configuration by a fastener, such as a Velcro-type fastener. Individual sections of the solar blanket 90 that include one or more solar panels 34 may be easily removable, such as by a snap-on connector, a sliding connector (e.g., a connector that allows a section to slide into a picture frame type slot in another section of the solar blanket), or by other connecting mechanisms. A handle may be attached to the blanket 90 so that it may be folded and easily carried separately from the suitcase 10.

The solar panels 34 may be replaceable. For example, the hinges 38 (FIG. 10) connecting adjacent solar panels 34 may allow adjacent solar panels 34 to separate from each other, e.g., by allowing the solar panels 34 to separate from the hinges 38, by allowing the hinges 38 to separate into multiple connectable parts, etc. As another example, when the solar panels 34 are provided in the solar blanket 90, the solar blanket 90 may be provided with a plurality pockets 92. One such exemplary pocket 92 is illustrated in FIGS. 7A-7C. In this embodiment, one or more solar panels 32 may be inserted into each pocket 92, and the pockets 92 may each include a panel 94, e.g., a transparent or translucent panel, through which the solar panels 34 may be visible. FIG. 7A shows the solar panel 34 outside the pocket 92 of the solar blanket 90 prior to insertion of the solar panel 34 into the pocket 92. FIG. 7B shows the solar panel 34 inserted into the pocket 92 so that it is visible through the panel 94 of the pocket 92. The pockets 92 may also include a fastener 96 for closing the pocket 92 to prevent the solar panels 34 from sliding out of the pockets 92. For example, the fastener 96 may include a flap 96 of material that includes Velcro 98 for closing the respective pocket 92. The solar panels 34 may include electrical conductors (not shown) that may exit the pocket 92 for connection with other solar panels 34 or downstream receiving components, or the electrical conductors of the solar panels 34 may connect to mating conductors formed within the individual pockets 92 as part of the blanket 90. FIG. 7C shows the solar panel 34 fastened inside the pocket 92 after folding over the flap 96 of material that includes Velcro 98 that holds the pocket 92 closed. As a result, individual solar panels 34 may be easily replaceable, e.g., if a solar panel 34 is broken or inoperable, instead of having to replace entire sub-arrays 32.

The wind turbine system 40 may include at least one wind turbine (not shown). The wind turbine may be capable of producing a power output of approximately 60 watts, but actual power output may vary with wind conditions, etc. The wind turbine may trickle charge the battery system 70 at wind speeds as low as approximately 5.75 miles per hour.

When deployed, the wind turbine body 44 and blades 46 may be mounted on the tripod 42. The tripod 42 may be compact and may include a height adjustable (telescoping) pole to provide a wind turbine, e.g., with a height of approximately 5.25 feet when deployed and a height of approximately 23.6 inches when folded for transport. The tripod 42 is strong and durable and designed for outdoor use. The wind turbine body 44 and blades 46 are disassembled from the tripod 42 when stored in the suitcase 10, and the wind turbine body 44 and blades 46 may be quickly and easily attached to a mounting plate (not shown) of the tripod 42, allowing for ease of deployment.

When deployed, the wind turbine blades 46 may be in an expanded configuration, and when stored, the wind turbine blades 46 may be in a collapsed configuration. The wind turbine blades 46 may be retractable by sliding into each other until collapsed. Alternatively, each of the blades 46 may fold at one or more points so that the wind turbine may having a large wing span may fit into the suitcase 10 with a smaller housing when stored. The blades 46 and/or one or more components of the wind turbine body 44 may be inflatable or otherwise capable of becoming more compact. When one or more components of the wind turbine system 40 are foldable, inflatable, retractable, or made more compact, the wind turbine system 40 may provide greater power density per size and weight. According to one embodiment, the wind turbine body 44 and blades 46 may have an extended height of approximately 62.6 inches and a retracted height of approximately 21.3 inches such that the wind turbine body 44 and blades 46 in the retracted configuration may fit neatly into the suitcase 10 for stowage and transport.

The voltage regulator 50 (e.g., for the wind turbine system 40 or other power generating device) may be provided to prevent overcharging. The voltage regulation may be pulse width modulation (PWM) type and designed to slow down the wind turbine as the battery system 70 becomes fully charged.

The battery system 70 includes one or more batteries, e.g., lithium-ion batteries or lead-acid batteries, for back-up system power. Lithium-ion batteries may have a higher energy density, and may be lighter and smaller. Additionally, lithium-ion batteries do not require charge controllers for battery charge control and monitoring since the controllers are integrated into the battery design, thereby minimizing the space and weight of the battery system 70. Each battery of the battery system 70 may be, for example, rated nominally at 72 ampere-hour (Ah) at 13.8 volts direct current (VDC) and may weigh approximately 23 pounds. Alternatively, the battery system 70 may include one or more fuel cells, an engine (e.g., a small, fuel-driven engine), etc.

When the battery system 70 includes a single battery, the suitcase 10 may still be “airline-checkable” as luggage, i.e., the suitcase 10 weighs less than approximately 70 pounds. Furthermore, when the battery system 70 includes one battery, the suitcase 10 may provide a battery backup capacity of approximately 3.5 hours.

One or more battery packs (not shown) may be added to the power system 20. Each battery pack may contain, for example, two batteries housed in a suitcase similar to the suitcase 10 shown in FIGS. 1 and 2 (excluding the power system 20). Since each battery may weigh approximately 23 pounds, the combination of the suitcase and the two batteries would comply with a 70-pound domestic checkable-luggage weight limit. Numerous suitcases 10 maybe be coupled together to provide an expandable power system. In addition, a plurality of suitcases 10 with or without power generating devices may be coupled together with other components/systems to provide more power and alternative capabilities.

The battery system 70 may be provided in a compartment in the suitcase 10. Alternatively, instead of or in addition to providing the battery system 70 inside the suitcase 10, the battery system 70 may be provided as one or more battery packs housed in one or more separate suitcases. As shown in FIG. 8, as another alternative, one or more battery packs may be removeably attachable to one or more exterior surfaces of the suitcase 10. For example, the battery pack may be removeably attachable to the exterior of the suitcase 10 using a fastening mechanism 74, such as a snap fit mechanism or a slide fastener mechanism. As a result, one or more battery packs may be separated from the exterior of the suitcase 10 prior to shipping, and then attached to the exterior of the suitcase 10 after shipping and prior to use. Accordingly, the suitcase 10 is modular, and since one or more battery packs may be removeable from the suitcase 10, the compliance with certain shipping regulations that limit weight or other contents of shipped containers (e.g., concentrations of batteries) may be easier.

Each additional battery may add additional battery backup capacity to the power system 20. For example, a battery pack carrying two batteries may add a total of approximately 7 hours of battery backup capacity to the power system 20, totaling approximately 10.5 hours of battery backup for the power system 20 plus additional battery pack. As a result, the power system 20 may be customized and configured to provide additional battery power using additional battery packs. Alternatively, the battery packs may also be customized and configured to have smaller or larger sizes and weights.

Alternatively, the suitcase 100 may include a temperature control system 72, such as a cooling system, a heating system, and/or a ventilation system, and may be thermostatically controlled. The temperature control system 72 may be provided in the battery system 70. Alternatively, the temperature control system 72 may be provided in a compartment of the suitcase 10 housing the battery system 70, and/or in a separate compartment in the suitcase, e.g., a main compartment or other compartment. The temperature control system 72 may be coupled to the battery system 70 and/or other electronics in the suitcase 10. For example, the temperature control system 72 may control the battery system 70 and/or the other electronics, e.g., to shut off the battery system 70 and/or the other electronics automatically if a temperature that is sensed by a sensor in the temperature control system 72 is above a particular threshold. The temperature control system 72 may be isolated from the electronics (e.g., the power system 20) so that dust is kept away from the electronics. The temperature control system 72 may include a compartment with a plurality of heat sinks and a fan that draws air across the plurality of heat sinks. The temperature control system 72 may also include an active or passive air circulation system, such as vents that allow air to enter and circulate inside the suitcase 10 or a fan. For example, a fan and/or a roof may be storable inside the suitcase 10 and deployable when in use. The fan may be external to the suitcase 10 when deployed and may cool the suitcause 10 when deployed. The roof may be made of canvas, metal, fabric, or other materials, and may cool and shade the suitcase 10 and other deployed components of the suitcase 10. As a result, less power may be necessary to maintain a lower temperature in the suitcase 10.

FIGS. 9 and 10 illustrate another suitcase 100, according to another embodiment. The suitcase 100 includes similar components as the suitcase 10 shown in FIGS. 1 and 2 except that the components included in the suitcase 100 shown in FIGS. 9 and 10 may be stored in a different configuration.

As shown in FIGS. 9 and 10, the suitcase 100 may include hinges 102 that allow sections 100a, 100b, 100c of the suitcase 100 to pivot (e.g., up to 180°) with respect to each other. The first and second layers 14, 16 of components may be stored in the first and second sections 100a, 100b, respectively, of the suitcase 100, and the third section 100c may serve as a lid or top of the suitcase 100. As shown in FIG. 9, the second and third sections 100b, 100c may be closed and locked together via the locking mechanisms 13. In order to access the interior of the first section 100a, the second and third sections 100b, 100c may pivot together and away from the first section 100a about the hinge 102 connecting the first and second sections 100a, 100b.

The first section 100a of the suitcase 100 may store the first (or bottom) layer 14 of components and may include one or more of the components described above, e.g., the foam 18 or other materials for separating the power system components, the input/output sockets 22, the solar array 30 including the foldable accordion-type honeycomb photovoltaic sub-array 32 and the handle 36, the wind turbine system 40 (including the tripod 42, the body 44, and the blades 46), the voltage regulator 50, the inverter 60, and/or the battery system 70. The wheels may be connected to an exterior surface of the first section 100a.

As shown in FIG. 10, in order to access the interior of the second section 100b, the first and second sections 100a, 100b may be closed and locked together via another set of locking mechanisms 13. Then, the third section 100c may pivot away from the first and second sections 100a, 100b about the hinge 102 connecting the second and third sections 100b, 100c.

The second section 100b of the suitcase 100 may store the second layer 16 of components, which may include a solar sub-array 32. The sub-array 32 in the second layer 16 may be provided in addition to one or more sub-arrays 32 stored in the first layer 14 or may be the sole sub-array 32 of the solar array 30 provided in the suitcase 100. As shown in FIG. 10, the sub-array 32 included in the second layer 16 may be integrated into the suitcase 100. Alternatively, the sub-array 32 may be removable from the interior of the suitcase 100 for deployment. Furthermore, the sub-array 32 may include a plurality of solar panels 34 connected by hinges 38 that allow the solar panels 34 to pivot 1800 with respect to an adjacent solar panel 34. The electrical connections that connect adjacent solar panels 34 may also be folded when the solar panels 34 are in the folded configuration. Also, a locking mechanism (not shown) may be provided to secure or hold the solar panels 34 in place in the suitcase 100 when the sub-array 32 is in the folded configuration. According to the embodiment shown in FIG. 10, a solar panel 34a may be permanently mounted to the suitcase 100 and centrally located with respect to the other solar panels 34. The other solar panels 34 may be connected to the permanently mounted solar panel 34a via the hinges 38. The solar panels 34 may be folded over via the hinges 38 so that they lie on top of the permanently mounted solar panel 34a when the sub-array 32 is in the folded configuration. When deploying the sub-array 32, the solar panels 34, except for the permanently mounted solar panel 34a, may pivot 1800 about the hinges 38 so that solar panels 34 lie alongside the permanently mounted solar panel 34a. Alternatively, the solar panels 34a, 34 may be provided in other configurations. As another alternative, the solar panel 34a may instead be removable to allow for deployment of the sub-array 32 at other locations. The solar panels 34a, 34 may be hardwired into the suitcase 100 or not hardwired to allow the user to more easily and quickly connect or disconnect the sub-array 32 from the suitcase 100. As a result, the second section 100b of the suitcase 100 may serve as a separate sub-array enclosure.

The first, second, and third sections 100a, 100b, 100c of the suitcase 100 may be closed and locked together via the locking mechanisms 13 connecting the first and second sections 100a, 100b and the locking mechanisms 13 connecting the second and third sections 100b, 100c. Then, the suitcase 100 may be carried using the handle 12. The sections 100a, 100b, 100c of the suitcase 100 may be made of a transparent material so that the components inside the suitcase 100 may be visible from the outside.

A glowing “Q” or other logo may be embedded on the exterior of the suitcase 10, 100, e.g., on a lid of the suitcase 10, 100, and the suitcase 10, 100 may be known as a “Q Case.”

As a result, the suitcase 10, 100 may provide hybrid renewable energy with advanced technology wind, solar, and/or other power generating systems, and may serve as a practical, portable renewable energy solution. The suitcase 10, 100 may be used in various applications, such as international relief efforts and disaster recovery, homeland security, communications, military, intelligence, energy and healthcare.

The power system 20 provided in the suitcase 10, 100 may be set up in minutes, expandable, and easily maintainable. The power system 20 may produce a large amount of power while its size and weight may be minimized.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A closeable case including a power system stored in an interior of the closeable case, comprising:
a power system, at least a portion of the power system being integral to the closeable case; and
at least one power generating device of the power system stored in the closeable case and at least partially removable from the closeable case.

2. The closeable case of claim 1, wherein the at least one power generating device includes a solar array.

3. The closeable case of claim 2, wherein the solar array is stored in the closeable case in a folded configuration.

4. The closeable case of claim 2, wherein the solar array is an accordion-type solar array.

5. The closeable case of claim 2, wherein the solar array includes a plurality of solar panels connected by at least one hinge.

6. The closeable case of claim 5, wherein the plurality of solar panels are stackable when the solar array is stored in the closeable case.

7. The closeable case of claim 5, wherein the plurality of solar panels includes a centrally located solar panel connected by a plurality of the hinges to a plurality of other solar panels.

8. The closeable case of claim 7, wherein the centrally located solar panel is permanently mounted to the closeable case.

9. The closeable case of claim 5, wherein the at least one solar panel is replaceable.

10. The closeable case of claim 1, wherein the at least one power generating device includes a wind turbine.

11. The closeable case of claim 10, wherein the wind turbine includes a plurality of blades, and the blades are capable of changing between an expanded configuration and a collapsed configuration.

12. The closeable case of claim 11, wherein the blades of the wind turbine are foldable, inflatable, retractable, or made more compact.

13. The closeable case of claim 1, wherein the closeable case includes at least one edible component.

14. The closeable case of claim 1, wherein the power system includes communications equipment for at least one of remote monitoring and remote control.

15. The closeable case of claim 1, wherein the closeable case is an airline-checkable suitcase.

16. The closeable case of claim 1, wherein the at least one power generating device includes a solar blanket including at least one solar panel.

17. The closeable case of claim 16, wherein the at least one solar panel of the solar blanket is attached to a flexible material.

18. The closeable case of claim 16, wherein the at least one solar panel is replaceable.

19. The closeable case of claim 1, further including a temperature control system configured to control a temperature within the closeable case.

20. The closeable case of claim 19, wherein the temperature control system includes a ventilation system.

21. The closeable case of claim 19, wherein the temperature control system is thermostatically controlled.

22. The closeable case of claim 19, wherein the temperature control system is isolated from the power system.

23. The closeable case of claim 1, wherein the power system includes a battery system.

24. The closeable case of claim 23, wherein at least a portion of the battery system is removably attachable to an exterior of the closeable case.

25. The closeable case of claim 1, further including a handle.

26. The closeable case of claim 1, wherein the closeable case is configured to be carried by a user.

27. The closeable case of claim 1, further including a first section of the closeable case that is configured to pivot with respect to a second section of the closeable case.

28. The closeable case of claim 27, wherein at least a portion of the power system is integral to at least one of the first and second sections.

29. The closeable case of claim 27, wherein the at least one power generating device is stored in and at least partially removable from at least one of the first and second sections.

30. The closeable case of claim 29, wherein the at least one power generating device is integral to the other of the at least one of the first and second sections.

31. The closeable case of claim 27, wherein the first and second sections of the closeable case are configured to be closed together.

33. A transportable power system comprising:
a first closeable case for storing at least one power generating device and at least one first battery, the at least one power generating device being removable from the first closeable case; and
a second closeable case for storing at least one second battery, the first and second batteries being capable of receiving power from the at least one power generating device.

34. The transportable power system of claim 33, wherein the at least one power generating device includes a solar array.

35. The transportable power system of claim 33, wherein the at least one power generating device includes a wind turbine.

36. The transportable power system of claim 33, wherein each of the first and second closable cases is an airline-checkable suitcase.

37. The transportable power system of claim 33, wherein at least a portion of the at least one first battery is removeably attachable to an exterior of the first closeable case.

38. A method of transporting a power system stored in an interior of a transportable case, comprising:
storing a power generating device of the power system within a first section of the transportable case;
transporting the transportable case to a desired location;
opening the transportable case by moving one of the first section and a second section of the transportable case with respect to the other of the first section and the second section of the transportable case;
removing at least a portion of the power generating device from within the first section of the transportable case;
receiving power from the power generating device; and
providing access to the received power.

39. The method of claim 38, wherein at least a portion of the power system is integral to at least one of the first section and the second section of the transportable case.

40. The method of claim 38, further including supplying power from the power generating device to a battery system.

41. The method of claim 40, further including removably attaching at least a portion of the battery system to an exterior of the transportable case.

42. The method of claim 38, further including controlling a temperature within the transportable case.

43. The method of claim 38, wherein the at least one power generating device includes a solar blanket including at least one solar panel.

44. The method of claim 43, wherein the at least one solar panel of the solar blanket is attached to a flexible material of the solar blanket.

45. The method of claim 38, wherein the transporting of the closeable case includes carrying the transportable case to the desired location.
